(19) United States
(12) Patent Application Publication
(10) Pub. No.: US 2003/0215751 A1
(43) Pub. Date: Nov. 20, 2003

(54) Method of removing resist using functional water and device therefor

(75) Inventors: Kiyoshi Otake, Ibaraki (JP); Nobuyuki Hishinuma, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Ushio Denki Kabushiki Kaisya, Tokyo (JP)

(21) Appl. No.: 10/441,061

(22) Filed: May 20, 2003

(30) Foreign Application Priority Data
May 20, 2002 (JP) 2002-144914

(51) Int. Cl. G03F 7/16; G03F 7/40; G03F 7/20; C25F 1/00; C25F 3/30; C25F 5/00; B08B 6/00; G03F 7/30

(52) U.S. Cl. 430/311; 430/328; 430/329; 134/1.3; 430/315

(57) ABSTRACT

A resist removal method and device therefor are provided that are excellent from the point of view of washing costs and environmental preservation and that also offer extremely high removal performance, and this method of resist removal using functional water according to the present invention includes the following steps:

(1) a step of irradiating a substrate to which resist has been applied with vacuum ultraviolet light of wavelength 172±10 nm;

(2) a step of substantially uniformly applying functional water to this resist surface; and

(3) a step of irradiating ultraviolet light of wavelength 190 to 310 nm onto this functional water.

### BACKGROUND OF THE INVENTION

1. Field of the Invention

The present invention relates to a method of resist treatment using functional water such as ozonized water and to a resist treatment device. In particular, it relates to treatment using functional water such as ozonized water and the optical energy of an excimer lamp.

2. Description of the Related Art

In the field of semiconductor manufacturing technology, with advances in increasing the fineness, increasing the density and increasing the degree of integration of circuit patterns, high-level technology is required whereby treatment processes of devices of various types can be performed without damage and without allowing impurities to adhere thereto.

Also, in semiconductor lithographic processes, various types of treatment are performed by applying a resist onto a substrate and using the resist pattern as a mask. Finally, however, the resist is removed from the substrate by performing so-called ashing treatment.

For this ashing, washing treatment is performed by immersion in a chemical treatment agent, using sulfuric acid (H₂SO₄) or hydrogen peroxide (H₂O₂), after removing most of the resist from the substrate, typically by a method employing oxygen plasma.

However, although depending on the type of resist and the device, ashing using oxygen plasma suffered from the fatal problem of causing damage to the device being treated and did not result in complete removal of the resist. Consequently, ashing using oxygen plasma had to be combined with treatment using a chemical treatment agent as described above. Furthermore, treatment using a chemical treatment agent is undesirable from the point of view of washing costs and environmental protection so there is a strong demand to reduce the amount of such chemical treatment agents employed.

Also, by-products are generated in the substrate and resist during the etching process, creating the problem that fully satisfactory removal of such by-products cannot be achieved by ashing using oxygen plasma or treatment using a chemical treatment agent.

In recent years, studies have been commenced into use of functional water such as ozonized water or ionized water as a substitute technique for the aforementioned treatments with chemical treatment agents (not just in the context of ashing but rather in the broader context of washing treatments in general).

However, washing methods employing functional water such as ozonized water or ionized water are usually batch type washing methods employing functional water on its own or in combination with ultrasound and the present situation is that these methods are inferior in terms of washing capability to washing methods employing large quantities of chemical treatment agents.

Furthermore, when treatment using functional water is employed in combination with another energy source such as ultrasound, in some cases the washing reaction of the functional water may not be conducted uniformly due to problems of energy distribution, leading to problems such as for example that the resist may be partially left behind during ashing.

### SUMMARY OF THE INVENTION

The problem to be solved by the present invention is to provide a method of resist treatment that is excellent from the point of view of washing costs or environmental protection and provides very high removal performance and a device therefor.

In view of the above problem, a method of resist removal employing functional water according to the present invention comprises the steps of:

(1) irradiating vacuum ultraviolet light of wavelength 172±10 nm onto a substrate onto which a resist has been applied;

(2) applying functional water substantially uniformly onto this resist surface; and

(3) irradiating ultraviolet light of wavelength 190 to 310 nm onto this functional water.

Furthermore, in the step of applying the functional water onto the resist surface, the functional water may be dropped onto this resist surface while rotating the substrate.

Furthermore, the functional water may be ozonized water, alkaline ionized water or acidic ionized water.

Also, in the step of irradiating ultraviolet light onto the functional water, ultraviolet light of wavelength 222±10 nm may be irradiated thereon.

Also, the vacuum ultraviolet light of wavelength 172±10 nm and/or the ultraviolet light of wavelength 222±10 nm may be produced by an excimer lamp.

Also, irradiation of this vacuum ultraviolet light of wavelength 172±10 nm and/or ultraviolet light of wavelength 190 to 310 nm thereon may be performed while the substrate is being rotated.

Also, a resist removal device employing the functional water according to the present invention may comprise a treatment chamber within the main body of the method device, this treatment chamber comprising: a stage that holds a substrate onto which a resist is applied; an excimer lamp that irradiates vacuum ultraviolet light of wavelength 172±10 nm onto this resist surface; a functional water supply mechanism that supplies functional water onto this resist surface; and an ultraviolet light emitting lamp that irradiates ultraviolet light of wavelength 190 to 310 nm onto this resist surface.

Also, a plurality of said treatment chambers may be formed, a stage that holds a substrate onto which the resist is applied and an excimer lamp that irradiates vacuum ultraviolet light of wavelength 172±10 nm onto this resist surface being provided in the first treatment chamber and a functional water supply mechanism that supplies functional water onto the resist surface and an ultraviolet light emitting lamp that irradiates ultraviolet light of wavelength 190 to 310 nm onto this resist surface being provided in the second treatment chamber.

Furthermore, a plurality of said second treatment chambers may be provided.

Also, a further aspect of the invention relates to a process for removing from the substrate by-products produced during etching rather than the process of removing this resist from a substrate having a resist (so-called ashing), comprising the steps of:

(1) irradiating vacuum ultraviolet light of wavelength 172±10 nm onto a substrate having by-products produced during etching;

(2) applying functional water substantially uniformly onto the surface of this substrate having by-products; and

(3) irradiating ultraviolet light of wavelength 190 to 310 nm onto this functional water.

### BRIEF DESCRIPTION OF THE DRAWINGS

FIG. 1 is a view showing a resist removal device according to the present invention;

FIG. 2 is a view showing a method of resist removal according to the present invention;

FIG. 3 is a view showing an excimer lamp employed in the present invention; and

FIG. 4 is a view showing another embodiment of a resist removal device according to the present invention.

### DESCRIPTION OF THE PREFERRED EMBODIMENTS

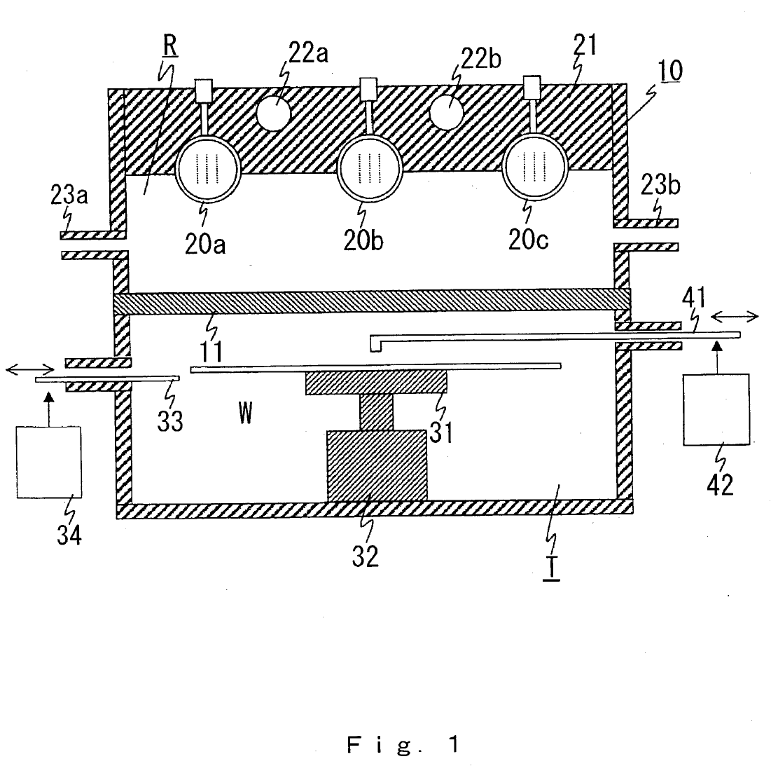

FIG. 1 is a schematic view showing an example of the construction of a device for putting into practice the resist removal method according to the present invention.

An ultraviolet ray treatment device 10, which is entirely covered with a casing made for example of stainless steel, comprises a lamp chamber R and treatment chamber T, defined by an ultraviolet-transparent member 11 therebetween.

In the interior of the lamp chamber R, excimer lamps 20 (20a, 20b, 20c) are arranged in gutter-shaped grooves of a metal block 21. Cooling water through-holes 22 (22a, 22b) through which cooling water is passed are provided in this metal block 21.

As shown in the drawing, the excimer lamps 20 are of circular shape in cross-section but their overall shape is roughly rod-shaped, extending in the direction perpendicular to the plane of the drawing. As will be described later, the arrangement of these lamps is that for example the lamp 20a and the lamp 20c emit vacuum ultraviolet light of wavelength 172 nm and the lamp 20b emits ultraviolet light of wavelength 222 nm.

An inert atmosphere of for example nitrogen gas is provided in the interior by providing an inert gas intake port 23a and exhaust port 23b in the sidewall of the lamp chamber R.

In the interior of the treatment chamber T, there are provided a stage 31 on which is placed a substrate W to be treated and a rotary mechanism 32 that rotates this stage 31. In the sidewall of the treatment chamber T, there is provided an aperture for feeding in and feeding out a treatment substrate W. The treatment substrate W is set in position on the stage 31 by means of a transfer arm 33. The transfer arm 33 is controlled by a feeding arm control mechanism 34.

Likewise, in the sidewall of the treatment chamber T, there is provided a nozzle aperture for inserting/retracting a functional water supply nozzle 41 into/from the chamber. This functional water supply nozzle 41 is controlled by means of a functional water supply nozzle control mechanism 42.

The apertures provided in the casing sidewall for the transfer arm 33 and functional water supply nozzle 41 are closed when the transfer arm 33 and functional water supply nozzle 41 are retracted from the treatment chamber T.

The distance between the ultraviolet-transparent member 11 and the substrate to be treated is for example 1 mm. These two can be made to approach each other during irradiation with ultraviolet light and these two can be moved away from each other when the transfer arm 33 and/or nozzle 41 is inserted, by means of the provision of a raising/lowering mechanism on the stage 31. Since, as already mentioned, the interior of the lamp chamber R is filled with an inert gas atmosphere, the distance between the excimer lamp and the ultraviolet-transparent member 11 does not pose any problems.

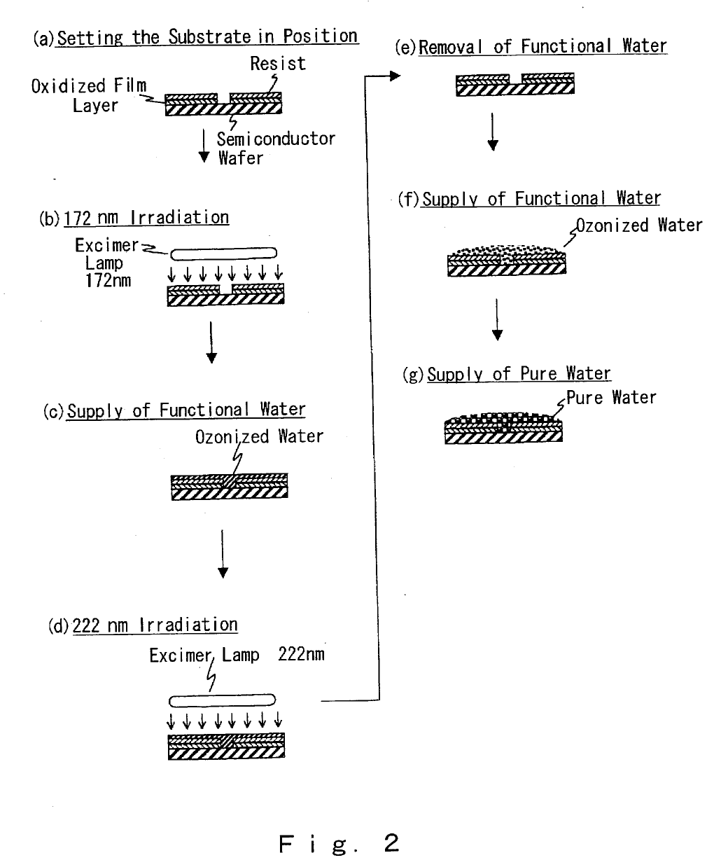

A resist removal method according to the present invention is described using the treatment sequence shown in FIG. 2 in addition to the treatment device shown in FIG. 1. The processing sequence in the Figure is shown by steps (a) to (g).

In (a), a semiconductor wafer (silicon wafer) W that has completed etching treatment is set in position on the stage 31. Resist is applied to the wafer W and an oxide film and/or metallic film is formed between the wafer W and the resist.

In (b), the excimer lamps 20a, 20c are lit and vacuum ultraviolet light of wavelength 172±10 nm, specifically, light of 172 nm, is irradiated onto the resist surface. The period of irradiation is for example 30 seconds and the light emission intensity of the excimer lamps 20 is 15 mW/mm².

Preferably, this irradiation with the excimer lamps is performed while rotating the stage 31. This is in order to irradiate the resist surface uniformly in cases where the lamps are for example rod-shaped lamps as shown in FIG. 1. The speed of revolution in this case may be for example 30 rpm.

In this way, formation of a uniform, thin layer of ozonized water in the succeeding steps can be achieved; this step can therefore be positioned as a pretreatment step.

In (c), functional water is supplied. This is achieved by inserting the functional water supply nozzle 41 into the treatment chamber T and dropping functional water, for example ozonized water, onto the resist surface from this nozzle 41. This dropping is performed for about 30 seconds at a pace of 2 cc/sec while rotating the stage 31 at for example 300 rpm. In this way, a layer of ozonized water of thickness 0.5 mm is uniformly formed on the surface of the resist. Functional water is supplied from for example a functional water manufacturing device arranged outside the treatment device. The ozonized water should contain at least 20 ppm of ozone in the water; for example an ozone content of content of 50 ppm is applied.

In this step, in combination with the foregoing excimer irradiation step, a thin, uniform layer of ozonized water can be formed. To give numerical values by way of example, a layer of not more than 1.0 mm, preferably 0.3 to 0.5 mm and even more preferably not more than 0.1 mm from the resist surface may be formed.

In (d), the functional water supply nozzle 41 is withdrawn from the treatment chamber T and ultraviolet light of wavelength 190 to 310 nm is directed onto the resist surface. Irradiation is performed by switching on the excimer lamp 20b and irradiating ultraviolet light of wavelength 190 to 310 nm, specifically, ultraviolet light of wavelength 222 nm, onto the aforementioned layer of ozonized water. The irradiation time is for example 30 seconds and the emission intensity of the excimer lamp 20 is 8 mW/mm².

Preferably also this irradiation is performed while the stage 31 is being rotated, the reason being, as mentioned above, in order to achieve uniform irradiation of the resist surface. The speed of rotation in this case is for example 30 rpm. The stage 31 can therefore be kept rotating during the steps (b), (c) and (d), the speed of rotation being changed in the respective steps.

By means of this step, the decomposition action of the ozonized water can be promoted using the radiation energy of the ultraviolet lamp, causing swelling of the resist present on the wafer surface. This “swelling” means that the resist can easily be removed from the oxide film or metallic layer.

It is effective to repeat the steps (c) and (d) a plurality of times, such as for example 4 to 5 times.

After this, the excimer lamp is turned off and the remaining resist is removed together with the functional water by rotating the stage 31 (step (e)). After this, functional water is again supplied for washing-off purposes (step (f)). In this process, the stage 31 is rotated at for example 1500 rpm and, in (f), ozonized water is dropped for 15 seconds at a rate of 2 cc/sec.

Furthermore, the wafer surface is washed by supplying pure water onto the wafer surface while rotating the stage. To give an example in terms of numerical values, water is dropped for 5 to 10 seconds at the rate of 5 cc/sec.

After this, the stage only is dried by rotation (without dropping any pure water or the like onto the stage).

Steps (e) to (g) remove (wash off) resist and/or byproducts remaining after completion of optical processing.

The following modifications, for example, can be made to the above treatment sequence.

The substrate to be treated is not restricted to a silicon wafer and a liquid-crystal substrate or ceramics substrate or other type of substrate could be adopted.

In the above embodiment, the case was described by way of example in which an oxide film was formed between the silicon wafer and the resist. However, instead of the oxide film, a metallic film layer such as for example copper (Cu) or aluminum (Al) could be employed.

There is no particular restriction regarding the type of resist that is held on the substrate and the present invention is applicable to all resists. Typical examples that may be given include novolak-based resists, chemical amplification type resists, or electron beam resists.

In step (b), the emission wavelength from the excimer lamp is not restricted to 172 nm and light in a range of 172±10 nm could be employed. For example light of 175 nm could be employed. Also, the irradiation time and irradiation intensity may of course be different depending on the processing throughput and on the type of resist and are not restricted to the embodiment described above.

In steps (c) and (f), the functional water is not restricted to ozonized water and alkaline ionized water or acidic ionized water could be employed or a mixture of these could be employed. Furthermore, the method of supplying the functional water is not restricted to dropping from a nozzle and other supply means could be employed. Also, although it is desirable from the point of view of forming the layer of functional water in uniform fashion that the stage should be rotated with respect to the supply of functional water, stage rotation is not essential and various rotational speeds or functional water supply paces could of course be adopted.

Also, in step (d), the emission wavelength from the ultraviolet lamp is not restricted to 222 nm and light of 190 to 310 nm could be employed.

Likewise, in the other steps, there is no restriction to the various example numerical values.

Also, treatment could be performed while the substrate is heated by providing a heating mechanism on the stage and the removal action can thereby be further speeded-up.

The number and arrangement of the excimer lamps are not restricted to the embodiment described above and other configurations could be adopted provided light of two types of wavelength can be satisfactorily directed thereby onto a substrate. Also, as will be described, the series of treatment processes described above need not necessarily be performed in the same device and different devices or containers could be provided for each step.

With the method of resist removal described above, in comparison with conventional ashing using oxygen plasma, the problems of damage to the device being treated can be eliminated and there is also no need for treatment with a chemical treatment agent, which creates environmental problems, following the oxygen plasma treatment.

Also, compared with washing (resist removal) treatment using only functional water such as ozonized water or ionized water, the resist method according to the present invention has much better washing performance, thanks to the accompanying use of irradiation by an excimer lamp. Furthermore, since irradiation of this resist surface with the excimer light is performed prior to dropping of the functional water onto the resist surface, the layer of functional water can be made extremely thin and uniform.

Also, although, in the etching step which is the step preceding this resist removal step, by-products i.e. so-called polymers may be formed on the resist, the method of resist removal according to the present invention has the advantage that these by-products can be satisfactorily removed.

It should be noted that the method according to the present invention could be applied not merely to wafers having a resist but also for example to the removal of the aforesaid by-products from wafers in respect of which resist removal has already been completed. In this case, the same treatment as in the case of the treatment sequence shown in FIG. 2 is performed but the object to be treated that is placed on the stage is a wafer, not having a resist, containing by-products after etching treatment.

The excimer lamps will now be described.

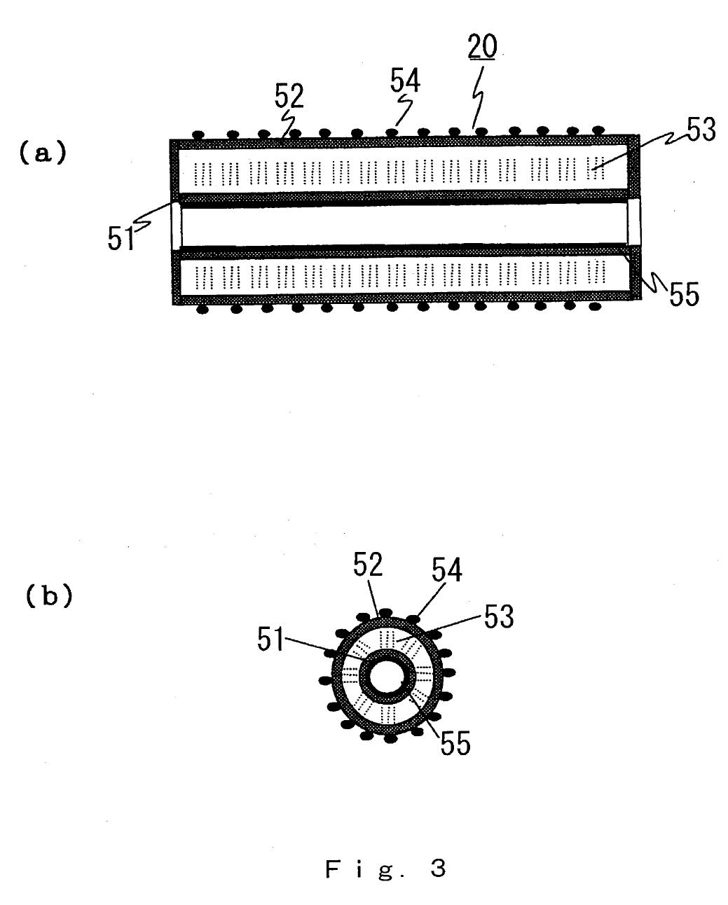

As shown in FIG. 3, the overall shape of the excimer lamps 20 is cylindrical; the material of the lamps is constituted of synthetic quartz that transmits vacuum ultraviolet light and that functions as a dielectric by dielectric barrier discharge. The discharge lamp 20 comprises a double cylindrical tube constituted by an inner tube 51 and outer tube 52 coaxially arranged and with a discharge space 53 formed between the inner tube 51 and outer tube 52 by closure at both ends thereof. The excimer molecules are formed by dielectric barrier discharge in the discharge space 53 and discharging gas whereby vacuum ultraviolet light is radiated from these excimer molecules, such as for example xenon gas, is sealed therein.

To give examples in terms of numerical values, the total length of a discharge lamp 20 may be 800 mm, its external diameter may be 27 mm, the external diameter of the inner tube 51 may be 16 mm, and the thickness of the inner tube 51 and outer tube 52 may be 1 mm.

A mesh electrode 54 is provided on the outer surface of the outer tube 52 while the other electrode constituted by an inner electrode 55 is provided within the inner tube 51. The mesh electrode 54 is of a seamless construction and overall is capable of extension/contraction so as to be capable of adhering closely to the outer tube 52. The inner electrode 55 is pipe-shaped or may be roughly C-shaped in cross-section, with a part thereof cut away, being arranged such that it adheres closely to the inner tube 51. A getter may be arranged in the discharge space 53 if required.

Vacuum ultraviolet light is emitted by connecting an AC power source between the mesh electrode 54 and inner electrode 55 so that excimer molecules are thereby formed in the discharge space 53.

Such an excimer lamp, in which radiation is effected by interposing a dielectric and a discharge space between electrodes, is also called a dielectric barrier discharge lamp and has the favorable characteristics, not found with the conventional low-pressure mercury discharge lamps or high-pressure arc discharge lamps, of providing strong emission of vacuum ultraviolet light of a single wavelength. This single-wavelength light is determined by the gas that is sealed in the discharge container: in the case of xenon gas (Xe), light of wavelength 172 nm is emitted, in the case of argon gas (Ar) and chlorine gas (Cl) light of wavelength 175 nm is emitted, in the case of krypton (Kr) and iodine (I), light of wavelength 191 nm is emitted, in the case of Argon (Ar) and fluorine (F), light of wavelength 193 nm is emitted, in the case of krypton (Kr) and bromine (Br), light of wavelength 207 nm is emitted, and in the case of krypton (Kr) and chlorine (Cl), light of wavelength 222 nm is emitted. Furthermore, such an excimer lamp has the feature that it can be made to flash and light instantaneously (within one second) if required.

The shape of the excimer lamp is not restricted to being cylindrical and for example a flat plate shape as shown in Japanese Patent Publication No. H. 8-21369 or a so-called “head-on” type lamp as shown in Japanese Patent No. 3043565 could be adopted. Also, the excimer lamp is not restricted to a discharge lamp in which discharge is effected with interposition of a dielectric; there are no restrictions regarding the form of discharge so long as excimer light emission can be achieved, for example by adopting an electrodeless discharge lamp that is excited by microwaves.

In the resist treatment method according to the present invention, in the first irradiation in step (b) (prior to dropping of functional water), vacuum ultraviolet light of wavelength 172±10 nm is employed: specifically, light of wavelength 172 nm obtained when xenon gas is sealed into the container or light of wavelength 175 nm obtained by sealing in argon gas and chlorine gas may be employed. Also, for the second irradiation (after dropping of functional water) in step (d), ultraviolet light of wavelength 190 to 310 nm may be employed. Specifically, in the case of an excimer lamp, light of wavelength 191 nm obtained using an container with krypton (Kr) and iodine (I) sealed therein, light of wavelength 193 nm obtained using an container with argon (Ar) and fluorine (F) sealed therein, light of wavelength 207 nm obtained using an container with krypton (Kr) and bromine (Br) sealed therein, or light of wavelength of 222 nm obtained using an container with krypton (Kr) and chlorine (Cl) sealed therein may be employed; in the case where a lamp which is not an excimer lamp is employed, a low-pressure mercury lamp that emits light of wavelength 254 nm or a mercury lamp that emits light of wavelength 308 nm may be employed; or an ArF laser or KrF laser may be employed.

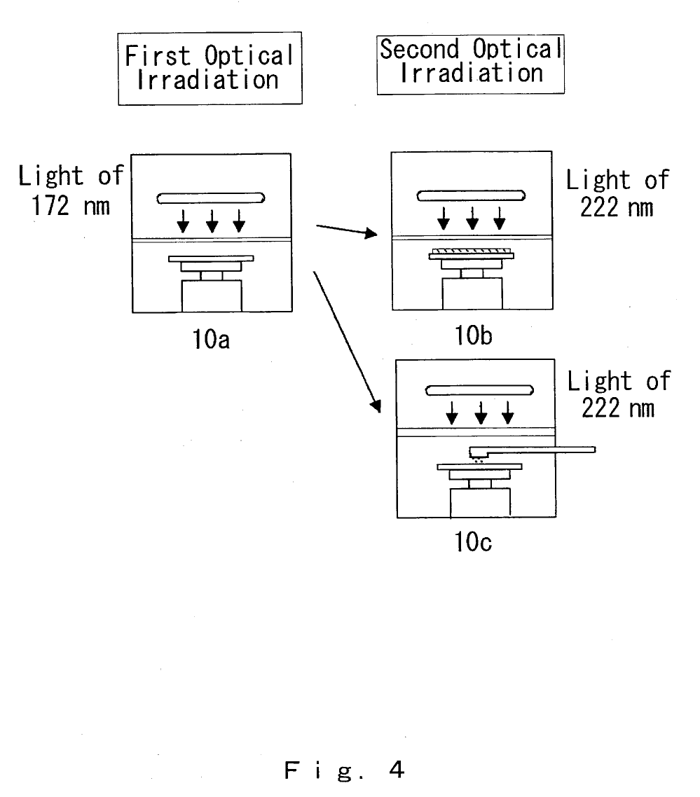

FIG. 4 shows another embodiment of a resist treatment device according to the present invention.

In this embodiment, the first irradiation prior to supply of functional water and the second irradiation after supplying functional water are performed in separate irradiation devices and the number of the second irradiation devices is more than the number of the first irradiation devices.

This is because the treatment time required in the second irradiation devices is two to three times the time required in the first irradiation devices, because the treatment process in the second irradiation devices requires dropping of functional water and concomitant insertion/retraction of the supply nozzle.

A treatment substrate whose treatment by the first irradiation device has been completed can therefore be treated by any of the plurality of second irradiation devices, so the problem of such treated substrates having to await further treatment can be eliminated.

The treatment sequence will now be described with reference to the drawings. First of all, the treatment substrate W1 is set in position in a first irradiation device 10a and is subjected to the first irradiation (wavelength 172 nm).

Next, after completing the irradiation treatment, the substrate W1 is fed to a second irradiation device 10b, where the substrate W1 is subjected to the second irradiation (wavelength 222 nm). When the substrate W1 in the first irradiation device 10a has been carried out, the next treatment substrate W2 is immediately fed in and set in position. However, since the treatment time t1 in the first irradiation device 10a is not more than half the treatment time t2 in the second irradiation device 10b, the treatment of the treatment substrate W2 in the first irradiation device 10a terminates earlier than the treatment of the treatment substrate W1 in the second irradiation device 10b. The treatment substrate W2 whose treatment in the first irradiation device 10a has thus been completed is therefore fed to the other, second irradiation device 10c, where it is subjected to the second irradiation treatment.

Thus, by making the number of second irradiation devices more than the number of first irradiation devices, the difference in treatment speed of these two types of device can be alleviated and the condition of awaiting treatment can be eliminated.

It should be noted that the number of the second irradiation devices is not restricted to two and a number greater than this could be provided. Also, a plurality of first irradiation devices could be provided. In this case, a greater number of second irradiation devices can be provided.

In addition, a control circuit may be provided that exercises control of the processing of the respective devices as a whole so that the treatments in the respective irradiation devices are conducted smoothly.

Tests to ascertain the beneficial effects of the resist removal method according to the present invention will now be described.

Tests of resist removal using an eight-inch wafer whose etching treatment had been completed were conducted.

The resist that was applied to the wafer was a chemical amplification resist.

For the first test, in a treatment process according to the present invention, resist removal was performed by conducting a first irradiation (light of 172±10 nm) and a second irradiation (light of 190 to 310 nm) and, thereafter, supplying ozonized water.

For the second test, in a treatment process for comparison purposes, resist removal was performed using ozonized water only, without conducting either the first irradiation (light of 172±10 nm) or the second irradiation (light of 190 to 310 nm).

For the third test, in a treatment process for comparison purposes, resist removal by a second irradiation and, thereafter, supplying ozonized water were conducted.

Whereas in the first test substantially 100% of the resist was removed, in the second test only about 5% of the resist was removed and in the third test about 60% of the resist was removed.

The results demonstrate that extremely high resist removal efficiency can be achieved by performing first irradiation of 172±10 nm and second irradiation of 190 to 310 nm, in accordance with the resist treatment method of the present invention.

It should be noted that although the resist removal method according to the present invention has the great advantage that use of a chemical treatment agent for post-treatment is unnecessary, this does not positively exclude the use of a chemical treatment agent and, depending on the circumstances, it would of course be possible to combine the resist removal method according to the present invention with use of a chemical treatment agent or the like.

Hydrofluoric acid treatment could also be performed and, if this is done, there is the benefit that more complete removal of any remaining oxide film can be achieved.

As described above, with the method of resist removal according to the present invention, the problem of damaging the device to be treated, compared with conventional ashing using oxygen plasma, is eliminated. Furthermore, there is no need to perform treatment with a chemical treatment agent, which causes environmental problems, after the oxygen plasma treatment. That is, the considerable benefits are obtained, not only that ashing using plasma is unnecessary but also that treatment with chemical treatment agent is unnecessary.

Also, compared with washing treatment (resist removal) using only functional water such as ozonized water or ionized water, washing performance is enormously improved thanks to the accompanying use of irradiation by an excimer lamp.

What is claimed is:

1. A method of removing resist employing functional water comprising the steps of:
irradiating vacuum ultraviolet light of wavelength 172±10 nm onto a substrate onto which a resist has been applied;
applying functional water substantially uniformly onto this resist surface; and
irradiating ultraviolet light of wavelength 190 to 310 nm onto this functional water.

2. The method of removing resist employing functional water according to claim 1, wherein the functional water is dropped onto this resist surface while rotating said substrate in the step of applying said functional water onto said resist surface.

3. The method of removing resist employing functional water according to claim 1, wherein said functional water is one of ozonized water, alkaline ionized water or acidic ionized water.

4. The method of removing resist employing functional water according to claim 1, wherein the ultraviolet light of wavelength 222±10 nm is irradiated thereon in the step of irradiating ultraviolet light onto said functional water.

5. The method of removing resist employing functional water according to claim 1, wherein the vacuum ultraviolet light of wavelength 172±10 nm and/or the ultraviolet light of wavelength 190 to 310 nm are/is irradiated by employing an excimer lamp.

6. The method of removing resist employing functional water according to claim 1, wherein the vacuum ultraviolet light of wavelength 172±10 nm and/or ultraviolet light of wavelength 190 to 310 nm are/is irradiated thereon while the substrate is being rotated.

7. A resist removal device employing functional water having a treatment chamber within the main body of the device,
this treatment chamber comprising:
a stage that holds a substrate onto which a resist is applied;
an excimer lamp that irradiates vacuum ultraviolet light of wavelength 172±10 nm onto this resist surface;
a functional water supply mechanism that supplies functional water onto this resist surface; and
an ultraviolet light emitting lamp that irradiates ultraviolet light of wavelength 190 to 310 nm onto this resist surface.

8. A resist removal device employing functional water having a plurality of treatment chambers within the main body of the device,
wherein a first treatment chamber comprises:
a stage that holds a substrate onto which resist is applied; and
an excimer lamp that irradiates vacuum ultraviolet light of wavelength 172±10 nm onto this resist surface; and
a second treatment chamber comprises:
a functional water supply mechanism that supplies functional water onto this resist surface; and
an ultraviolet light emitting lamp that irradiates ultraviolet light of wavelength 190 to 310 nm onto this resist surface.

9. The resist removal device employing functional water according to claim 7, wherein a plurality of said second treatment chambers are provided.

10. A method for removing by-products from a substrate having by-products produced during etching, comprising the steps of:
irradiating vacuum ultraviolet light of wavelength 172±10 nm on the substrate having by-products;
applying functional water substantially uniformly onto the surface of the substrate having by-products; and
then irradiating ultraviolet light of wavelength 190 to 310 nm onto this functional water thereafter.
